(19) United States
(12) Patent Application Publication
(10) Pub. No.: US 2016/0268353 A1
(43) Pub. Date: Sep. 15, 2016

(54) LIGHT EMITTING DEVICE, SIGN LAMP, AND DISPLAY SYSTEM

(71) Applicant: Kabushiki Kaisha Toshiba, Minato-ku (JP)

(72) Inventors: Tomoaki SAWABE, Sumida (JP); Tomio ONO, Yokohama (JP); Keiji SUGI, Fujisawa (JP); Shintaro ENOMOTO, Yokohama (JP)

(73) Assignee: Kabushiki Kaisha Toshiba, Minato-ku (JP)

(21) Appl. No.: 15/164,118

(22) Filed: May 25, 2016

Related U.S. Application Data
(63) Continuation of application No. PCT/JP2013/081964, filed on Nov. 27, 2013.

(51) Int. Cl. H01L 27/32; H01L 51/50; F21V 23/06; F21V 23/00; F21V 23/04

(52) U.S. Cl. CPC H01L 27/3239; F21V 23/003; F21V 23/0435; F21V 23/06; H01L 51/504; H01L 51/5016; H01L 2251/5361

(57) ABSTRACT

According to one embodiment, a light-emitting device includes a first light emitter, a second light emitter. The first light emitter includes a first organic layer and a second organic layer. The first organic layer includes a fluorescent material to emit a first light having a first light emission spectrum. The second organic layer is stacked with the first organic layer in a first direction. The second organic layer includes a first phosphorescent material to emit a second light having a second light emission spectrum different from the first light emission spectrum. The second light emitter includes a third organic layer to emit a third light having a third light emission spectrum different from the first light emission spectrum and the second light emission spectrum. A triplet energy of the fluorescent material is higher than a triplet energy of the first phosphorescent material.

### CROSS-REFERENCE TO RELATED APPLICATIONS

This is a continuation application of International Application PCT/JP2013/081964, filed on Nov. 27, 2013; the entire contents of which are incorporated herein by reference.

### FIELD

Embodiments described herein relate generally to a light-emitting device, sign lamp, and display system.

### BACKGROUND

There is a light-emitting device that uses an organic light-emitting diode (OLED). There is a sign lamp that uses such a light-emitting device. There is a display system that uses multiple sign lamps. It is desirable for the light-emitting devices used in the sign lamps and the like to display various colors. High luminous efficiency of the light-emitting devices also is desirable.

### BRIEF DESCRIPTION OF THE DRAWINGS

FIG. 1 is a cross-sectional view schematically showing the light-emitting device according to the first embodiment;

FIG. 2A to FIG. 2C are schematic views showing a portion of the light-emitting device according to the first embodiment;

FIG. 3 is a graph of an example of the characteristics of the light-emitting device according to the first embodiment;

FIG. 4 is a schematic view showing an example of the characteristics of the light-emitting device according to the first embodiment;

FIG. 5A and FIG. 5B are graphs of examples of other characteristics of the light-emitting device according to the first embodiment;

FIG. 6A to FIG. 6C are cross-sectional views schematically showing other light-emitting devices according to the first embodiment;

FIG. 7 is a plan view schematically showing a sign lamp as an example of the light-emitting device according to the second embodiment;

FIG. 8 is a partial cross-sectional view schematically showing a portion of the sign lamp according to the second embodiment;

FIG. 9 is a partial cross-sectional view schematically showing a portion of another sign lamp according to the second embodiment;

FIG. 10 is a partial cross-sectional view schematically showing a portion of another sign lamp according to the second embodiment;

FIG. 11A to FIG. 11C are schematic views showing a sign lamp according to a third embodiment.

FIG. 12 is a cross-sectional view schematically showing an example of a segment;

FIG. 13 is a cross-sectional view schematically showing another example of a segment; and

FIG. 14 is a block diagram schematically showing a display system according to a fourth embodiment.

### DETAILED DESCRIPTION

According to one embodiment, a light-emitting device includes a first light emitter, a second light emitter. The first light emitter includes a first organic layer and a second organic layer. The first organic layer includes a fluorescent material to emit a first light having a first light emission spectrum. The second organic layer is stacked with the first organic layer in a first direction. The second organic layer includes a first phosphorescent material to emit a second light having a second light emission spectrum different from the first light emission spectrum. The second light emitter includes a third organic layer to emit a third light having a third light emission spectrum different from the first light emission spectrum and the second light emission spectrum. A triplet energy of the fluorescent material is higher than a triplet energy of the first phosphorescent material.

Various embodiments will be described hereinafter in detail with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

A light-emitting device according to a first embodiment will now be described. The light-emitting device includes a first light emitter and a second light emitter. The first light emitter includes a first organic layer and a second organic layer stacked in a first direction.

The first light emitter includes a first organic layer and a second organic layer, where the first organic layer includes a fluorescent material emitting a first light having a first light emission spectrum, and the second organic layer includes a first phosphorescent material emitting a second light having a second light emission spectrum different from the first light emission spectrum.

The second light emitter includes a third organic layer emitting a third light having a third light emission spectrum different from the first light emission spectrum and the second light emission spectrum.

The triplet energy of the fluorescent material is higher than the triplet energy of the first phosphorescent material. For example, white light is obtained when adding the first light emission spectrum, the second light emission spectrum, and the third light emission spectrum. The third organic layer includes, for example, a second phosphorescent material different from the first phosphorescent material.

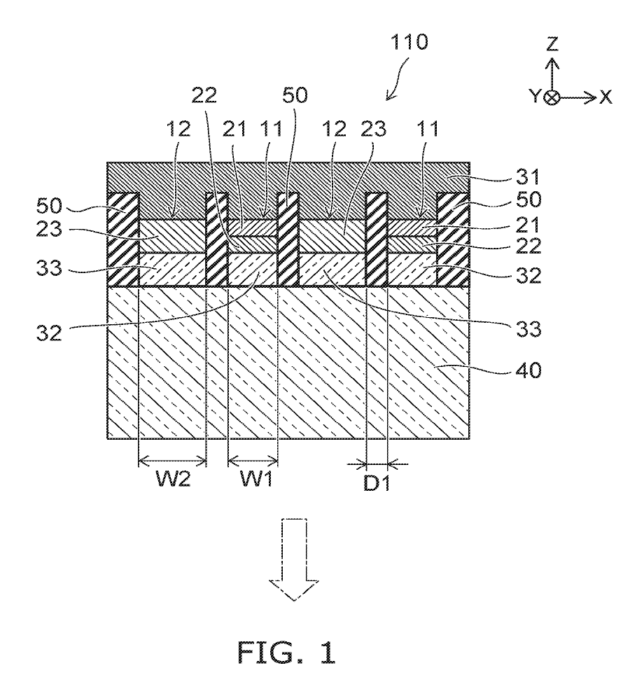

FIG. 1 is a cross-sectional view schematically showing the light-emitting device according to the first embodiment.

As shown in FIG. 1, the light-emitting includes a first light emitter 11 and a second light emitter 12.

The first light emitter 11 includes a first organic layer 21 and a second organic layer 22. The second organic layer 22 is stacked with the first organic layer 21 in the first direction. For example, the second organic layer 22 contacts the first organic layer 21. For example, an intermediate layer may be provided between the first organic layer 21 and the second organic layer 22. The first organic layer 21 and the second organic layer 22 include organic light-emitting layers.

The second light emitter 12 is arranged with the first light emitter 11. In the example, the second light emitter 12 is arranged with the first light emitter 11 in a second direction perpendicular to the first direction. The second light emitter 12 includes a third organic layer 23. The third organic layer 23 includes an organic light-emitting layer.

Here, a direction parallel to the first direction is taken as a Z-axis direction. One direction perpendicular to the Z-axis direction is taken as an X-axis direction. A direction perpendicular to the X-axis direction and the Z-axis direction is taken as a Y-axis direction. In the example, the second light emitter 12 is arranged with the first light emitter 11 in the X-axis direction. In other words, in the example, the X-axis direction is the second direction. The second direction is not limited to the X-axis direction and may be, for example, the Y-axis direction. The second direction may be any direction perpendicular to the Z-axis direction (the first direction).

The light-emitting device 110 includes, for example, the multiple first light emitters 11 and the multiple second light emitters 12. In the example, the multiple first light emitters 11 and the multiple second light emitters 12 are arranged alternately in the X-axis direction. The number of the first light emitters 11 and the number of the second light emitters 12 are arbitrary. There may be one first light emitter 11 and one second light emitter 12.

In the case where the first light emitter 11 and the second light emitter 12 are arranged in the X-axis direction, a width W1 in the X-axis direction of the first light emitter 11 is, for example, not less than 5 μm and not more than 1 mm. A width W2 in the X-axis direction of the second light emitter 12 is, for example, not less than 5 μm and not more than 1 mm. A distance D1 between the first light emitter 11 and the second light emitter 12 is, for example, not less than 5 μm and not more than 1 mm. It is sufficient for the width W1 in the X-axis direction of the first light emitter 11, the width W2 in the X-axis direction of the second light emitter 12, and the distance D1 between the first light emitter 11 and the second light emitter 12 to be such that these are not visually confirmed by the viewer; and these widths are appropriately designed to match the application. For example, when a human having 1.0 vision views from a distance of 1 m, the width W1 in the X-axis direction of the first light emitter 11, the width W2 in the X-axis direction of the second light emitter 12, and the distance D1 between the first light emitter 11 and the second light emitter 12 cannot be visually confirmed as lines by the viewer if these widths are set to be 100 μm or less. However, this is a reference example for isolated lines; and the width W1 in the X-axis direction of the first light emitter 11, the width W2 in the X-axis direction of the second light emitter 12, and the distance D1 between the first light emitter 11 and the second light emitter 12 are not limited thereto.

The light-emitting device 110 further includes, for example, a first electrode 31, a second electrode 32, a third electrode 33, a substrate 40, and an insulating layer 50.

The first electrode 31 is electrically connected to the first light emitter 11 and the second light emitter 12. In the example, the first electrode 31 is electrically connected to each of the multiple first light emitters 11 and the multiple second light emitters 12. For example, the first electrode 31 opposes each of the multiple first light emitters 11 and the multiple second light emitters 12 in the Z-axis direction. In the example, the first electrode 31 is electrically connected to the first organic layer 21 of each of the multiple first light emitters 11. The first electrode 31 may be made of multiple conductive units.

The second electrode 32 is electrically connected to the first light emitter 11. In the example, the second electrodes 32 are multiply provided. The multiple second electrodes 32 are electrically connected respectively to the multiple first light emitters 11. In the example, the multiple second electrodes 32 are electrically connected respectively to the second organic layers 22 of the multiple first light emitters 11.

In the example, the first light emitter 11 is provided between the first electrode 31 and the second electrode 32. More specifically, the first organic layer 21 is provided between the first electrode 31 and the second electrode 32; and the second organic layer 22 is provided between the first organic layer 21 and the second electrode 32. Conversely, the second organic layer 22 may be provided between the first electrode 31 and the second electrode 32; and the first organic layer 21 may be provided between the second organic layer 22 and the second electrode 32.

Thereby, a current is supplied to the first light emitter 11 by applying a voltage between the first electrode 31 and the second electrode 32. Light is emitted from the first organic layer 21 and the second organic layer 22 due to the supply of the current.

The third electrode 33 is electrically connected to the second light emitter 12. In the example, the third electrodes 33 are multiply provided. The multiple third electrodes 33 are electrically connected respectively to the multiple second light emitters 12. In other words, the multiple third electrodes 33 are electrically connected respectively to the multiple third organic layers 23. For example, the third electrodes 33 are electrically connected to the second electrodes 32. For example, the third electrodes 33 may be electrically insulated from the second electrodes 32.

In the example, the second light emitter 12 is provided between the first electrode 31 and the third electrode 33. Thereby, a current is supplied to the second light emitter 12 by applying a voltage between the first electrode 31 and the third electrode 33. Light is emitted from the third organic layer 23 due to the supply of the current.

For example, the third electrode 33 may be electrically connected to the second electrode 32. In the example, the second electrode 32 that is electrically connected to the second organic layer 22 is provided; and the third electrode 33 that is electrically connected to the third organic layer 23 is provided. This is not limited thereto; and, for example, similarly to the first electrode 31, one continuous electrode may be electrically connected to the second organic layer 22 and the third organic layer 23.

Thus, the light emission of the first light emitter 11 and the light emission of the second light emitter 12 are controlled independently. Accordingly, only the first light emitter 11 or only the second light emitter 12 can be caused to emit light. Or, both the first light emitter 11 and the second light emitter 12 can be caused to emit light. Accordingly, three types of light can be obtained by switching the control of the light-emitting device 110. In other words, the light-emitting device 110 in which the light emission colors are switchable can be obtained.

The substrate 40 is arranged with the first light emitter 11 and the second light emitter 12 in the Z-axis direction. The substrate 40 opposes the first electrode 31 in the Z-axis direction. In the example, the second electrode 32 is provided between the substrate 40 and the first electrode 31. The first light emitter 11 is provided between the second electrode 32 and the first electrode 31. The third electrode 33 is provided between the substrate 40 and the first electrode 31. The second light emitter 12 is provided between the third electrode 33 and the first electrode 31.

In other words, the second electrode 32 and the third electrode 33 are arranged on the substrate 40. The first light emitter 11 is provided on the second electrode 32. The second light emitter 12 is provided on the third electrode 33. The first electrode 31 is provided on the first light emitter 11 and the second light emitter 12.

The substrate 40 is light-transmissive. The substrate 40 is, for example, transparent. The first electrode 31 is light-reflective. The second electrode 32 and the third electrode 33 are light-transmissive. The second electrode 32 and the third electrode 33 are, for example, transparent. For example, the light reflectance of the first electrode 31 is higher than the light reflectance of the substrate 40, the light reflectance of the second electrode 32, and the light reflectance of the third electrode 33.

Thereby, in the light-emitting device 110, the light that is emitted from the first light emitter 11 is emitted to the outside by passing through the second electrode 32 and the substrate 40. The light that is emitted from the second light emitter 12 is emitted to the outside by passing through the third electrode 33 and the substrate 40. In other words, the light-emitting device 110 is a so-called bottom-emission type.

The insulating layer 50 is provided between the first light emitter 11 and the second light emitter 12. In the example, for example, the multiple insulating layers 50 are provided. The multiple insulating layers 50 are provided respectively in the regions between the multiple first light emitters 11 and the multiple second light emitters 12. For example, the insulating layers 50 are filled into the gaps between the first electrode 31, the substrate 40, the first light emitters 11, and the second light emitters 12.

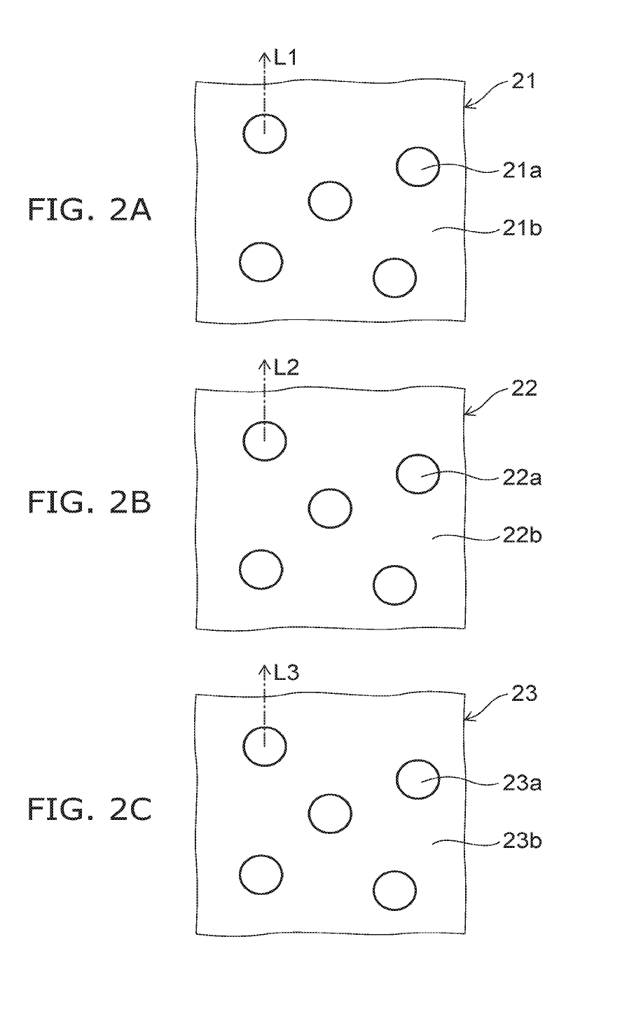

FIG. 2A to FIG. 2C are schematic views showing a portion of the light-emitting device according to the first embodiment.

As shown in FIG. 2A, the first organic layer 21 includes a fluorescent material unit 21a. The fluorescent material unit 21a includes a fluorescent material. The fluorescent material of the fluorescent material unit 21a emits a first light L1 having a first light emission spectrum due to the supply of the current. The first organic layer 21 includes, for example, the multiple fluorescent material units 21a. The first organic layer 21 further includes, for example, a first host material unit 21b. The first host material unit 21b includes a first host material. In the first organic layer 21, for example, the multiple fluorescent material units 21a exist in a state of being dispersed in the first host material unit 21b.

As shown in FIG. 2B, the second organic layer 22 includes a first phosphorescent material unit 22a. The first phosphorescent material unit 22a includes a first phosphorescent material. The first phosphorescent material of the first phosphorescent material unit 22a emits a second light L2 having a second light emission spectrum due to the supply of the current. The second light emission spectrum of the second light L2 is different from the first light emission spectrum of the first light L1. The second organic layer 22 includes, for example, the multiple first phosphorescent material units 22a. The second organic layer 22 further includes, for example, a second host material unit 22b. The second host material unit 22b includes a second host material. In the second organic layer 22, for example, the multiple first phosphorescent material units 22a exist in a state of being dispersed in the second host material unit 22b.

As shown in FIG. 2C, the third organic layer 23 includes, for example, a second phosphorescent material unit 23a. The second phosphorescent material unit 23a includes a second phosphorescent material. The second phosphorescent material of the second phosphorescent material unit 23a emits a third light L3 having a third light emission spectrum due to the supply of the current. The third light emission spectrum of the third light L3 is different from the first light emission spectrum of the first light L1 and the second light emission spectrum of the second light L2. The third organic layer 23 includes, for example, the multiple second phosphorescent material units 23a. The third organic layer 23 further includes, for example, a third host material unit 23b. The third host material unit 23b includes a third host material. In the third organic layer 23, for example, the multiple second phosphorescent material units 23a exist in a state of being dispersed in the third host material unit 23b. The third organic layer 23 is not limited to a phosphorescent material and may include, for example, a fluorescent material.

In FIG. 2A to FIG. 2C, the fluorescent material unit 21a, the first phosphorescent material unit 22a, and the second phosphorescent material unit 23a are shown as having spherical configurations for convenience. The configurations of the fluorescent material unit 21a, the first phosphorescent material unit 22a, and the second phosphorescent material unit 23a are not limited to spherical configurations and may be any configuration.

Here, a “fluorescent material” is, for example, a material that emits fluorescence. “Fluorescence” is, for example, photoluminescence generated as a result of the transition from a photo-excited singlet energy level to a low level and is generated within about 10 ns after the excitation. A “phosphorescent material” is, for example, a material that emits phosphorescence. “Phosphorescence” is, for example, photoluminescence generated as a result of the transition from a triplet energy level to a low level and is generated within about 10 μs after the excitation.

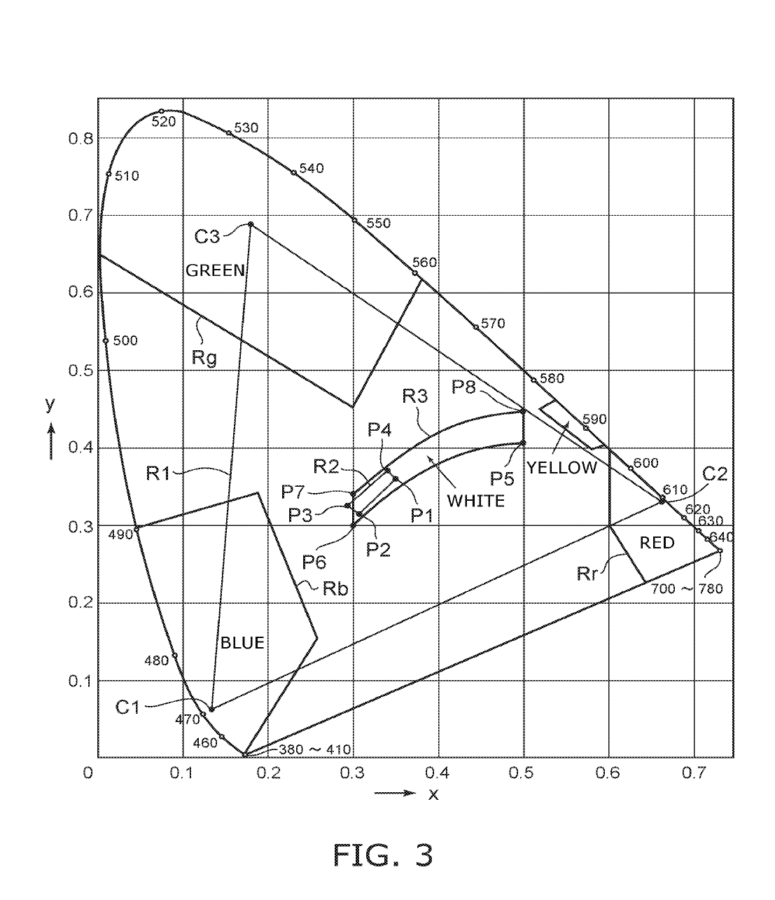

FIG. 3 is a graph of an example of the characteristics of the light-emitting device according to the first embodiment.

FIG. 3 is a graph of the (x, y) chromaticity coordinates of CIE 1931 of examples of a first color C1 (the first light emission spectrum) of the first light L1 emitted from the fluorescent material unit 21a of the first organic layer 21, a second color C2 (the second light emission spectrum) of the second light L2 emitted from the first phosphorescent material unit 22a of the second organic layer 22, and a third color C3 (the third light emission spectrum) of the third light L3 emitted from the second phosphorescent material unit 23a of the third organic layer 23.

In the light-emitting device 110 as shown in FIG. 3, a first region R1 that is surrounded with the first color C1, the second color C2, and the third color C3 includes a second region R2 surrounded with a first point P1, a second point P2, a third point P3, and a fourth point P4. The (x, y) chromaticity coordinates (hereinbelow, called the chromaticity coordinates) of the first point P1 are (0.350, 0.360). The chromaticity coordinates of the second point P2 are (0.305, 0.315). The chromaticity coordinates of the third point P3 are (0.295, 0.325). The chromaticity coordinates of the fourth point P4 are (0.340, 0.370).

The second region R2 is substantially white. The first region R1 is set to include the second region R2. Thereby, a mixed color of the first color C1, the second color C2, and the third color C3 can be substantially white. The color temperature of the second region R2 is, for example, not less than 4000 K and not more than 8500 K.

In the example, the first region R1 further includes a third region R3 surrounded with a fifth point P5, a sixth point P6, a seventh point P7, and an eighth point P8. The chromaticity coordinates of the fifth point P5 are (0.500, 0.405). The chromaticity coordinates of the sixth point P6 are (0.300, 0.300). The chromaticity coordinates of the seventh point P7 are (0.300, 0.340). The chromaticity coordinates of the eighth point P8 are (0.500, 0.445). However, in the third region R3, the locus between the fifth point P5 and the sixth point P6 is an isanomal corresponding to the black body locus. Similarly, the locus between the seventh point P7 and the eighth point P8 is an isanomal corresponding to the black body locus.

The first region R1 is set to include the third region R3. Thereby, for example, the diversity of the colors displayable using the mixed color of the first color C1, the second color C2, and the third color C3 can be increased.

For example, the chromaticity coordinates of the first color C1 are included in a region Rb surrounded with (0.05, 0.3), (0.187, 0.35), (0.26, 0.154), and (0.174, 0.005). However, in the region Rb, the locus between point (0.05, 0.3) and point (0.174, 0.005) is the spectrum locus. This is merely an example; and the chromaticity coordinates of the first color C1 are not limited thereto.

In other words, in the example, the first color C1 is substantially blue. The first light L1 is substantially blue light. The peak wavelength of the first light L1 is, for example, not less than 380 nm and not more than 490 nm.

For example, the chromaticity coordinates of the second color C2 is included in a region Rr surrounded with (0.65, 0.22), (0.6, 0.3), (0.6, 0.4), and (0.74, 0.26). However, in the region Rr, the locus between point (0.65, 0.22) and point (0.74, 0.26) is the purple boundary. The locus between point (0.6, 0.4) and point (0.74, 0.26) is the spectrum locus. This is merely an example; and the chromaticity coordinates of the second color C2 are not limited thereto.

In other words, in the example, the second color C2 is substantially red. The second light L2 is substantially red light. The peak wavelength of the second light L2 is, for example, not less than 570 nm and not more than 780 nm.

For example, the chromaticity coordinates of the third color C3 are included in a region Rg surrounded with (0.38, 0.62), (0.3, 0.45), and (0, 0.65). However, in the region Rg, the locus between point (0.38, 0.62) and point (0, 0.65) is the spectrum locus. This is merely an example; and the chromaticity coordinates of the third color C3 are not limited thereto.

In other words, in the example, the third color C3 is substantially green. The third light L3 is substantially green light. The peak wavelength of the third light L3 is, for example, not less than 490 nm and not more than 570 nm.

Thus, the first color C1 is set to be included in the region Rb; the second color C2 is set to be included in the region Rr; and the third color C3 is set to be included in the region Rg. Thereby, the second region R2 can be included in the first region R1. For example, the first color C1, the second color C2, and the third color C3 can be measured by a spectrometer.

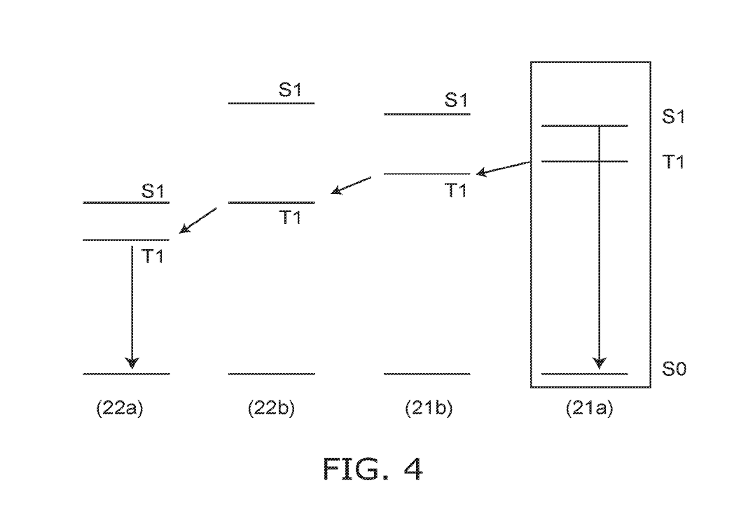

FIG. 4 is a schematic view showing an example of the characteristics of the light-emitting device according to the first embodiment.

FIG. 4 is a schematic view showing the singlet excited state energy levels and the triplet excited state energy levels of the first organic layer 21 and the second organic layer 22 and the energy transfer of the excitons.

In the light-emitting device according to the first embodiment as shown in FIG. 4, the triplet energy (the T1 energy) of the fluorescent material unit 21a is higher than the first phosphorescent material unit energy. Generally, the T1 energy is smaller than the singlet energy (the S1 energy). Also, the energy of light is inversely proportional to the wavelength. In other words, the energy of light increases as the wavelength becomes short. Accordingly, as recited above, for example, the fluorescent material unit 21a includes a fluorescent material emitting blue light; and the first phosphorescent material unit 22a includes a phosphorescent material emitting red light. Thereby, the triplet energy of the fluorescent material unit 21a can be set to be higher than the first phosphorescent material unit energy.

In the example, the triplet energy of the second host material unit 22b is higher than the first phosphorescent material unit energy. The triplet energy of the first host material unit 21b is higher than the triplet energy of the second host material unit 22b. The triplet energy of the fluorescent material unit 21a is higher than the triplet energy of the first host material unit 21b.

The singlet energy (the S1 energy) of the first host material unit 21b is higher than the singlet energy of the fluorescent material unit 21a. The singlet energy of the second host material unit 22b is higher than the singlet energy of the first host material unit 21b. The singlet energy of the second host material unit 22b is higher than the singlet energy of the first phosphorescent material unit 22a.

As recited above, the singlet energy of the first host material unit 21b is higher than the singlet energy of the fluorescent material unit 21a. Thereby, for example, the diffusion into the first host material unit 21b of the singlet excitons generated at the interface between the fluorescent material unit 21a and the first host material unit 21b is suppressed. Therefore, the energy of the singlet excitons is consumed as energy producing the first light L1 inside the fluorescent material unit 21a. Accordingly, the first light L1 (the fluorescence of the first color) is emitted from the fluorescent material unit 21a due to the singlet excitons.

On the other hand, the triplet energy of the first host material unit 21b is lower than the triplet energy of the fluorescent material unit 21a. The triplet energy of the second host material unit 22b is lower than the triplet energy of the first host material unit 21b. The first phosphorescent material unit energy is lower than the triplet energy of the second host material unit 22b.

Therefore, the triplet excitons of the fluorescent material unit 21a diffuse through the first host material unit 21b and the second host material unit 22b and reach the first phosphorescent material unit 22a. Thereby, the energy of the triplet excitons is consumed as energy producing the second light L2 in the first phosphorescent material unit 22a; and the second light L2 is emitted from the first phosphorescent material unit 22a.

In an organic layer, the excitons are generated by the recombination of the charge. It is known that about 25% of the excitons generated at this time are singlet excitons; and the remaining about 75% are triplet excitons. A fluorescent material converts only the singlet excitons into light emission. Therefore, the internal quantum efficiency of the fluorescent material is about 25%.

Conversely, even in the case where the fluorescent material unit 21a is used in the light-emitting device 110, the energy of the triplet excitons generated by the fluorescent material unit 21a can be utilized by the first phosphorescent material unit 22a. In other words, the energy of the triplet excitons generated by the fluorescent material unit 21a is not lost. Thereby, high luminous efficiency can be obtained in the light-emitting device 110. For example, the internal quantum efficiency can approach substantially 100%.

For example, it has been proposed to use a light-emitting device including organic layers in emergency escape route lighting. The specification of white and the specification of green are determined for escape route lighting (e.g., JIS-Z-9103). For example, an element that emits white light and an element that emits green light are provided in configurations to match the pattern of the escape route lighting in the light-emitting device including the organic layers. Thereby, the pattern of the escape route lighting can be displayed.

It is necessary for the escape route lighting to be able to be driven by a battery for 30 minutes when the electrical power supply is interrupted. Therefore, high luminous efficiency is necessary for the organic layer. From the perspective of the luminous efficiency, it is desirable to use a phosphorescent material in the organic layer. On the other hand, white light having a high color temperature (e.g., 4000 K to 8500 K) is necessary in the escape route lighting. In the case where the organic layer includes a phosphorescent material, it is difficult to realize white light having the color temperature determined for the escape route lighting. For example, in the case where white light is realized by mixing blue light, red light, and green light, it is necessary for the blue light to be deep blue (e.g., having a peak wavelength of 470 nm or less). However, it is difficult for phosphorescent materials to realize deep blue with high reliability. In the case where the organic layer includes a fluorescent material, deep blue can be realized; but as recited above, the luminous efficiency undesirably decreases.

The light-emitting device 110 according to the embodiment includes the first organic layer 21 including the fluorescent material unit 21a, the second organic layer 22 including the first phosphorescent material unit 22a, and the third organic layer 23 including the second phosphorescent material unit 23a.

Thereby, for example, deep blue can be realized by the first color C1 of the first organic layer 21. For example, the first region R1 is set to include the second region R2. Thereby, for example, white light having a high color temperature can be realized. In the case where only the phosphorescent material is used in the light-emitting device 110, white having a high color temperature that is difficult to display can be displayed. In the light-emitting device 110, compared to the case where only the phosphorescent material is used, it is possible to display various colors. For example, the first region R1 is set to include the third region R3. Thereby, for example, it is possible to display more various colors.

In the light-emitting device 110 according to the embodiment, the energy of the triplet excitons generated by the fluorescent material unit 21a can be utilized by the first phosphorescent material unit 22a; and high luminous efficiency is obtained. Thus, in the light-emitting device 110 according to the embodiment, high luminous efficiency and the display of various colors can be realized.

The first organic layer 21 may include, for example, a mixed material of a host material and a dopant (the fluorescent material unit 21a) emitting blue light. For example, CBP (4,4′,-bis(N-carbazolyl)-1,1′-biphenyl), DSA-Ph (1,4-di-[4-(N,N-di-phenyl)amino]styryl-benzene), BCzVBi (4,4′-bis(9-ethyl-3-carbazovinylene)-1,1′-biphenyl), etc., are examples of the host material included in the first organic layer 21. For example, DPVBi (4,4-bis(2,2-diphenyl-ethene-1-yl)biphenyl), TBADN (9,10-bis(2-naphthyl)-2-tertial-butylanthracene), MQAB (difluoro(6-mesityl-N-2-1H-quinolinylidene-N-6-mesityl-2-quinol inaminato-N1 boron), etc., are examples of the blue light-emitting dopant included in the first organic layer 21.

The second organic layer 22 may include, for example, a mixed material of a host material and a dopant (the first phosphorescent material unit 22a) emitting red light. For example, CBP α-NPD (bis(N-(1-naphthyl-N-phenylbenzidine), mCP (1,3-bis(N-carbazolyl)benzene), TAPC (di-[4-(N,N-ditolylamino)phenyl]cyclohexane), TCTA (4,4′,4″-tris(9-carbazolyl)-triphenylamine), OXD-7 (1,3-bis(2-(4-tertiary butylphenyl)-1,3,4-oxydiazole-5-yl)benzene), Bphen (4,7-diphenyl-1,10-phenanthroline), BAlq (bis(2-methyl-8-quinolinolate)-4-(phenylphenolate)aluminum), etc., are examples of the host material included in the second organic layer 22. For example, Ir(MDQ)₂(acac)(bis(2-methyldibenzo-[f,h]quinoxaline)(acetylacetonate)iridium(III)), Ir(piq)₃tris(1-phenylsoquinoline)iridium(III), etc., are examples of the red light-emitting dopant included in the second organic layer 22.

The third organic layer 23 may include, for example, a mixed material of a host material and a dopant (the second phosphorescent material unit 23a) emitting green light. For example, CBP, etc., are examples of the host material included in the third organic layer 23. For example, Ir(ppy)₃(tris(2-phenylpyridine)iridium(III)), Ir(mppy)₃(tris(2-(p-tolyl)pyridine)iridium(III)), Ir(hflpy)(acac)(bis(2-(9,9-dihexyfluorenyl)-1-pyridine)(acetylacetonate)iridium(III)), etc., are examples of the green light-emitting dopant included in the third organic layer 23.

The first electrode 31 that is light-reflective includes, for example, at least one of aluminum or silver. For example, the first electrode 31 includes aluminum. An alloy of silver and magnesium may be used as the first electrode 31. The thickness (the length in the Z-axis direction) of the first electrode 31 is, for example, 5 nanometers (nm) or more.

The second electrode 32 and the third electrode 33 that are light-transmissive may include, for example, an oxide including at least one type of element selected from the group consisting of In, Sn, Zn, and Ti. The second electrode 32 and the third electrode 33 may include, for example, conductive glass (e.g., NESA or the like) including indium oxide, zinc oxide, tin oxide, indium tin oxide (ITO), fluorine-doped tin oxide (FTO), indium zinc oxide, etc. For example, the second electrode 32 and the third electrode 33 may be formed by vapor phase epitaxy such as sputtering, vapor deposition, etc. For example, the second electrode 32 and the third electrode 33 may be formed by coating, spraying, etc. For example, the second electrode 32 and the third electrode 33 function as positive electrodes.

The substrate 40 includes, for example, quartz glass, alkali glass, alkali-free glass, etc. The substrate 40 may include, for example, a transparent resin such as polyethylene terephthalate, polycarbonate, polymethyl methacrylate, polypropylene, polyethylene, amorphous polyolefin, a fluoric resin, etc.

The first light emitter 11 and the second light emitter 12 may further include a not-shown first functional layer and a not-shown second functional layer as necessary. For example, the not-shown first functional layer is provided between the second organic layer 22 and the second electrode 32 or between the third organic layer 23 and the third electrode 33.

The thickness of the first functional layer is, for example, not less than 1 nanometer (nm) and not more than 500 nanometers (nm).

For example, the first functional layer functions as a hole injection layer. In the case where the first functional layer functions as the hole injection layer, the first functional layer includes, for example, PEDPOT:PPS poly(3,4-ethylenedioxythiophene)-poly(styrenesulfonic acid), CuPc (copper phthalocyanine), MoO₃ (molybdenum trioxide), etc.

For example, the first functional layer functions as a hole transport layer. In the case where the first functional layer functions as the hole transport layer, the first functional layer includes, for example, α-NPD (4,4′-bis[N-(1-naphthyl)-N-phenylamino]biphenyl), TAPC (1,1-bis[4-[N,N-di(p-tolyl)amino]phenyl]cyclohexane), m-MTDATA (4,4′,4″-tris[phenyl(m-tolyl)amino]triphenylamine), TPD (bis(3-methyl phenyl)-N,N′-diphenylbenzidine), TCTA (4,4′,4″-tri(N-carbazolyl)triphenylamine), etc.

The first functional layer may include a layer functioning as a hole injection layer stacked with a layer functioning as a hole transport layer. In such a case, the layer that functions as the hole injection layer is for improving the injection characteristics of the holes. The layer that functions as the hole injection layer is provided between the second electrode 32 and the layer functioning as the hole transport layer or between the third electrode 33 and the layer functioning as the hole transport layer.

The not-shown second functional layer is provided between the first organic layer 21 and the first electrode 31 or between the third organic layer 23 and the first electrode 31. The thickness of the second functional layer is, for example, not less than 1 nanometer (nm) and not more than 500 nanometers (nm).

For example, the second functional layer functions as an electron transport layer. The second functional layer includes, for example, Alq3 (tris(8-hydroxyquinolinato)aluminum(III)), BAlq (bis(2-methyl-8-quinolilato-N1,08)-(1,1′-biphenyl-4-olato)aluminum), Bphen (bathophenanthroline), 3TPYMB (tris[3-(3-pyridyl)-mesityl]borane), etc.

For example, the second functional layer functions as an electron injection layer. In such a case, the second functional layer includes, for example, lithium fluoride, cesium fluoride, a lithium quinoline complex, etc.

The second functional layer may include a layer functioning as an electron transport layer stacked with a layer functioning as an electron injection layer. In such a case, the layer that functions as the electron injection layer is for improving the injection characteristics of the electrons. The layer that functions as the electron injection layer is provided between the first electrode 31 and the layer functioning as the electron transport layer.

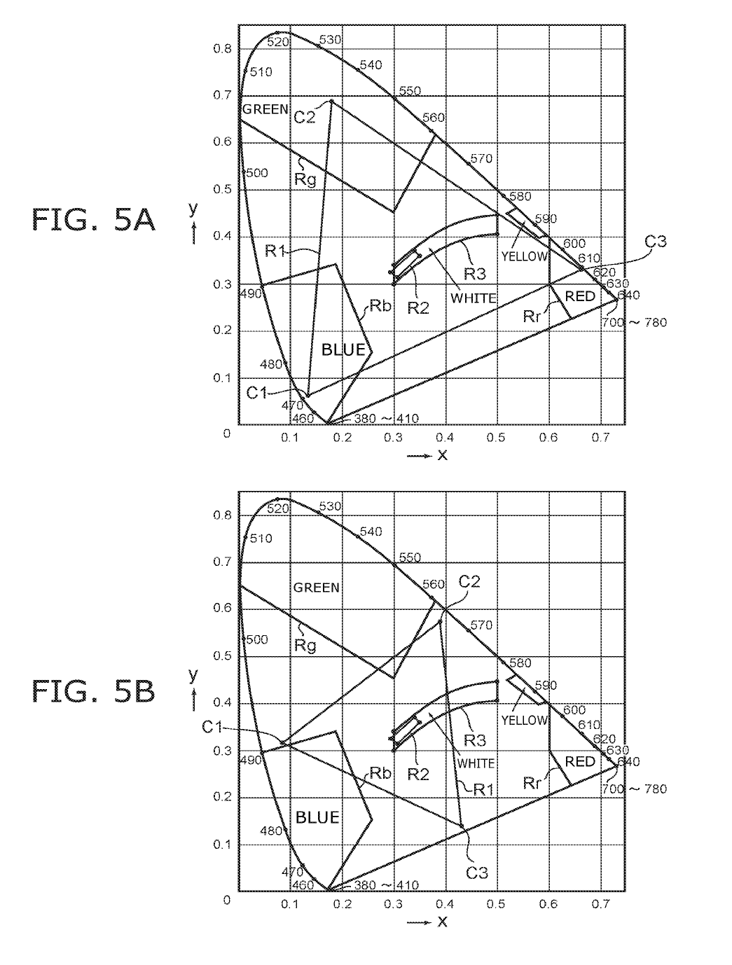

FIG. 5A and FIG. 5B are graphs of examples of other characteristics of the light-emitting device according to the first embodiment.

In the example as shown in FIG. 5A, the chromaticity coordinates of the first color C1 are included in the region Rb; the chromaticity coordinates of the second color C2 are included in the region Rg; and the chromaticity coordinates of the third color C3 are included in the region Rr. In other words, in the example, the first color C1 is substantially blue; the second color C2 is substantially green; and the third color C3 is substantially red.

Thus, even in the case where the first color C1 is set to blue, the second color C2 is set to green, and the third color C3 is set to red, similarly to the description recited above, the triplet energy of the fluorescent material unit 21a can be set to be higher than the first phosphorescent material unit energy. For example, the region R2 can be included in the region R1. Accordingly, high luminous efficiency and the display of various colors can be realized.

As shown in FIG. 5B, for example, the first color C1 may be set to a color between blue and green. For example, the second color C2 may be set to a color between green and red. For example, the third color C3 may be set to a color between red and blue. In such a case as well, similarly to the description recited above, the triplet energy of the fluorescent material unit 21a can be set to be higher than the first phosphorescent material unit energy. For example, the region R2 can be included in the region R1.

Thus, the first color C1, the second color C2, and the third color C3 may not necessarily be included in the region Rr, the region Rg, and the region Rb. For example, the first color C1, the second color C2, and the third color C3 may be any color (wavelength) such that the triplet energy of the fluorescent material unit 21a can be higher than the first phosphorescent material unit energy and the region R2 can be included in the region R1.

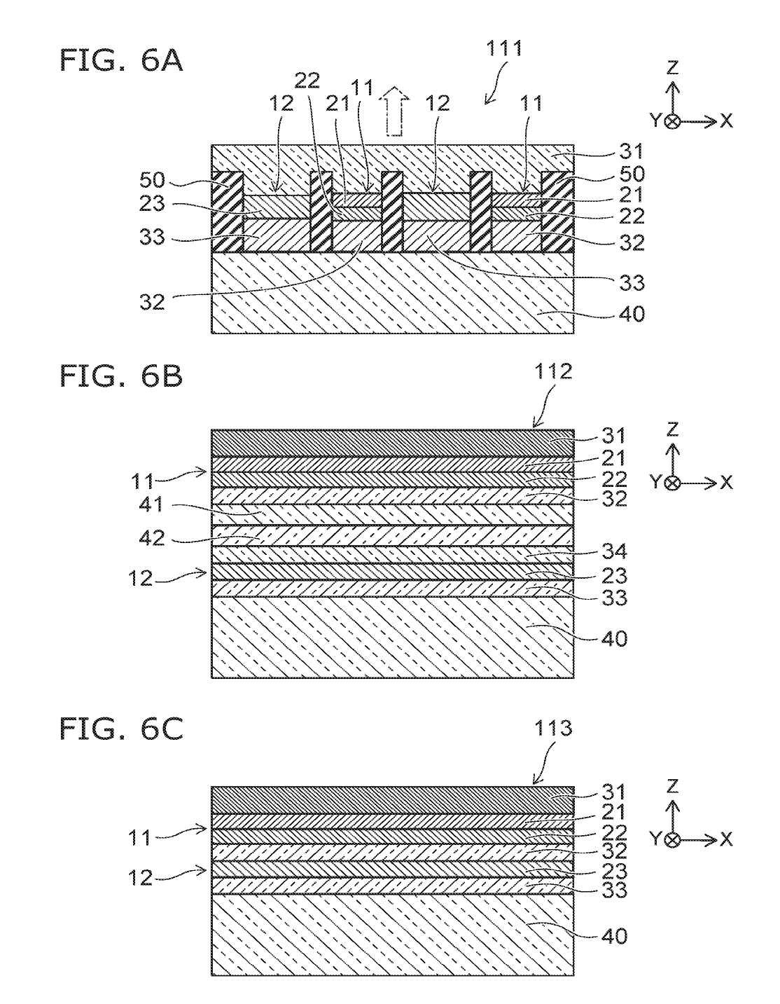

FIG. 6A to FIG. 6C are cross-sectional views schematically showing other light-emitting devices according to the first embodiment.

In a light-emitting device 111 as shown in FIG. 6A, the first electrode 31 is light-transmissive; and the second electrode 32 and the third electrode 33 are light-reflective. In the light-emitting device 111, the light reflectance of the first electrode 31 is, for example, lower than the light reflectance of the second electrode 32 and the light reflectance of the third electrode 33. The first electrode 31 is, for example, transparent.

In the light-emitting device 111, the light that is emitted from the first light emitter 11 passes through the first electrode 31 and is emitted to the outside. The light that is emitted from the second light emitter 12 also passes through the first electrode 31 and is emitted to the outside. In other words, the light-emitting device 111 is a so-called top-emission type. Thus, the light-emitting device according to the embodiment may be the bottom-emission type or may be the top-emission type.

In a light-emitting device 112 as shown in FIG. 6B, the first light emitter 11 is provided between the first electrode 31 and the substrate 40. The second electrode 32 is provided between the first light emitter 11 and the substrate 40. The second light emitter 12 is provided between the second electrode 32 and the substrate 40. The third electrode 33 is provided between the second light emitter 12 and the substrate 40.

The light-emitting device 112 further includes a fourth electrode 34 and substrates 41 and 42. The fourth electrode 34 is provided between the second electrode 32 and the second light emitter 12. The substrate 41 is provided between the second electrode 32 and the fourth electrode 34. The substrate 42 is provided between the substrate 41 and the fourth electrode 34.

In other words, in the light-emitting device 112, the third electrode 33, the second light emitter 12, the fourth electrode 34, the substrate 42, the substrate 41, the second electrode 32, the first light emitter 11, and the first electrode 31 are stacked in this order on the substrate 40.

In the light-emitting device 112, the first light emitter 11 is provided between the first electrode 31 and the second electrode 32. The second light emitter 12 is provided between the third electrode 33 and the fourth electrode 34. A voltage is applied between the first electrode 31 and the second electrode 32. Thereby, light is emitted from the first light emitter 11. A voltage is applied between the third electrode 33 and the fourth electrode 34. Thereby, light is emitted from the second light emitter 12.

For example, the first electrode 31 is light-reflective in the example. The second to fourth electrodes 32 to 34 and the substrates 40 to 42 are light-transmissive. Thereby, the light that is emitted from the first light emitter 11 and the second light emitter 12 is emitted from the substrate 40 to the outside. In other words, the device is the bottom-emission type.

For example, the third electrode 33 may be light-reflective; and the first electrode 31, the second electrode 32, the fourth electrode 34, and the substrates 41 and 42 may be light-transmissive. In such a case, the light that is emitted from the first light emitter 11 and the second light emitter 12 is emitted from the first electrode 31 to the outside. In other words, the device is the top-emission type.

Thus, in the light-emitting device 112, the second light emitter 12 is arranged with the first light emitter 11 in the Z-axis direction. As shown in the light-emitting device 110, etc., the second light emitter 12 may be arranged in a direction perpendicular to the direction in which the first organic layer 21 and the second organic layer 22 are arranged; and as shown in the light-emitting device 112, the second light emitter 12 may be arranged in the direction in which the first organic layer 21 and the second organic layer 22 are arranged.

In a light-emitting device 113 as shown in FIG. 6C, the first light emitter 11 is provided between the first electrode 31 and the substrate 40. The second electrode 32 is provided between the first light emitter 11 and the substrate 40. The second light emitter 12 is provided between the second electrode 32 and the substrate 40. The third electrode 33 is provided between the second light emitter 12 and the substrate 40.

In the light-emitting device 113, the first light emitter 11 is provided between the first electrode 31 and the second electrode 32. The second light emitter 12 is provided between the second electrode 32 and the third electrode 33. In the light-emitting device 113, light is emitted from the first light emitter 11 by applying a voltage between the first electrode 31 and the second electrode 32. Light is emitted from the second light emitter 12 by applying a voltage between the second electrode 32 and the third electrode 33. In other words, in the light-emitting device 113, the second electrode 32 is used commonly by the first light emitter 11 and the second light emitter 12.

Thus, in the case where the first light emitter 11 and the second light emitter 12 are arranged in the Z-axis direction, one electrode may be shared by the first light emitter 11 and the second light emitter 12.

### Second Embodiment

The light-emitting device may include a first light-emitting region that includes the first light emitter and the second light emitter, and a second light-emitting region that is arranged with the first light-emitting region. The first light-emitting region and the second light-emitting region are arranged in a first surface intersecting the first direction. For example, the first direction is orthogonal to the first surface.

The second light-emitting region includes a fourth organic layer that emits the third light having the third light emission spectrum. For example, the fourth organic layer includes the material used to form the third organic layer. For example, the fourth organic layer is made of the material used to form the third organic layer.

The third organic layer and the fourth organic layer include, for example, the second phosphorescent material that is different from the first phosphorescent material.

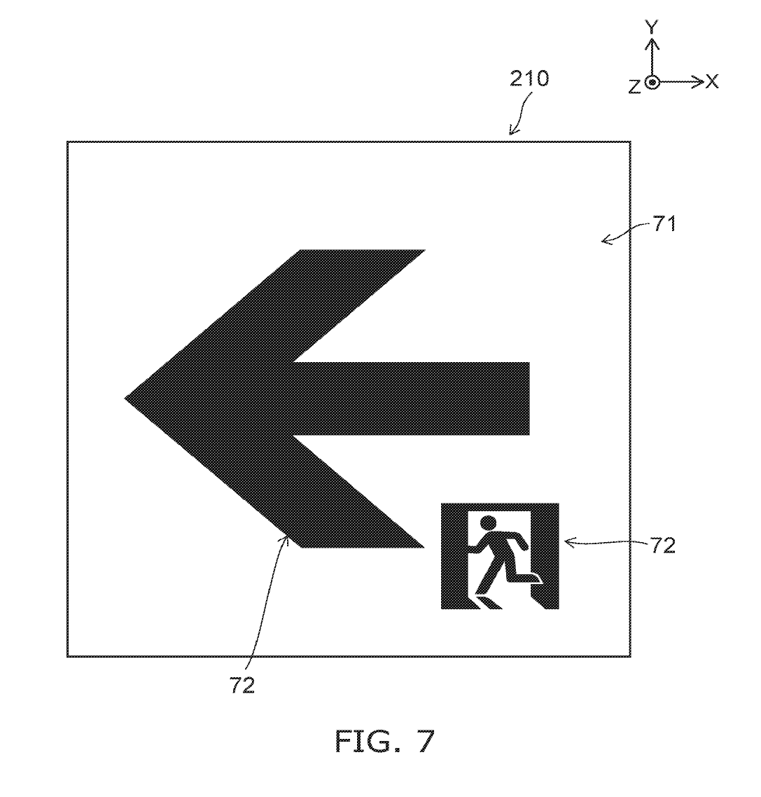

FIG. 7 is a plan view schematically showing a sign lamp as an example of the light-emitting device according to the second embodiment.

As shown in FIG. 7, the sign lamp 210 includes a first element unit 71 (a first light-emitting region) and a second element unit 72 (a second light-emitting region). The second element unit 72 is arranged with the first element unit 71 in a direction perpendicular to the Z-axis direction. The sign lamp 210 includes, for example, one first element unit 71 and multiple second element units 72. The number of the first element units 71 and the number of the second element units 72 are arbitrary. There may be one or multiple first element units 71 and one or multiple second element units 72. In the sign lamp 210, the elements that are functionally and configurationally substantially the same as those of the light-emitting devices described in the first embodiment recited above are marked with the same reference numerals; and a detailed description is omitted.

The first element unit 71 and the second element unit 72 are, for example, light-emitting devices including organic layers. The sign lamp 210 displays a prescribed pattern using the light emitted from the first element unit 71 and the light emitted from the second element unit 72. The pattern is, for example, a symbol mark (a pictogram), characters, etc.

In the example, escape route lighting is shown as the sign lamp 210. The sign lamp 210 is not limited to the escape route lighting. The sign lamp 210 may be, for example, a medical sign lamp, a broadcast sign lamp, etc. The medical sign lamp is, for example, a sign lamp during surgery, during X-ray imaging, etc. The broadcast sign lamp is, for example, a sign lamp (a so-called on-air lamp) indicating that broadcasting is in progress, etc. The sign lamp 210 may be any device that displays a prescribed pattern by emitting light.

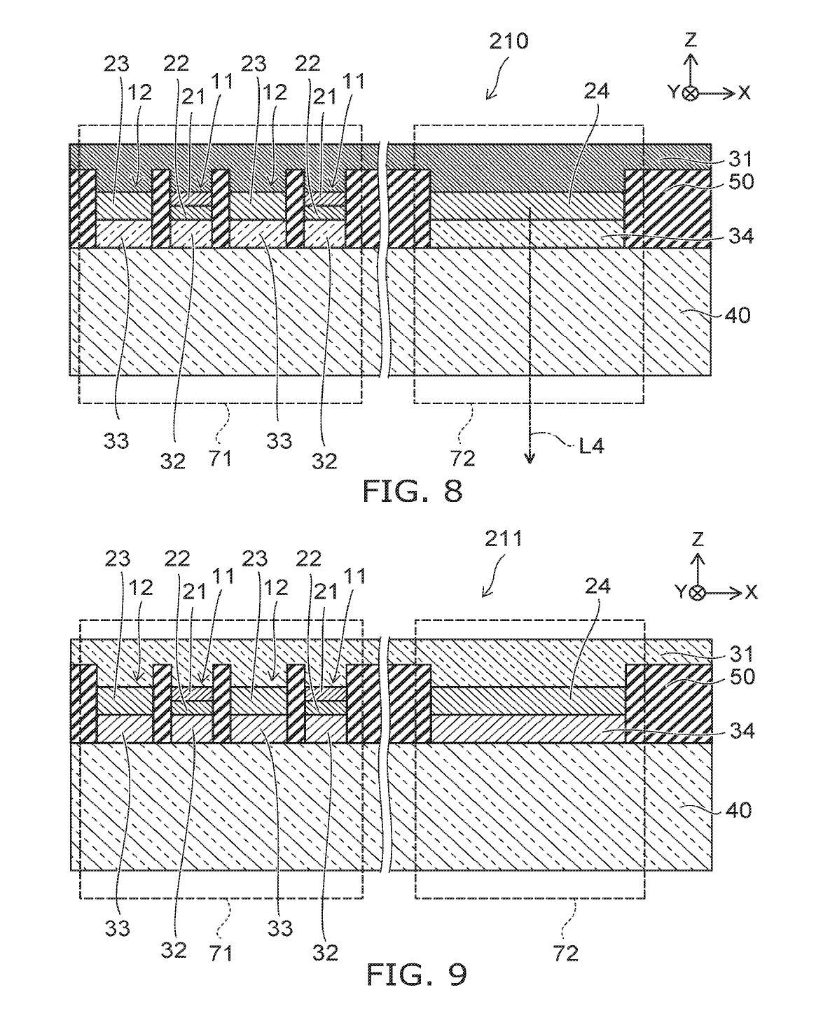

FIG. 8 is a partial cross-sectional view schematically showing a portion of the sign lamp according to the second embodiment.

As shown in FIG. 8, the first element unit 71 includes the first light emitter 11 and the second light emitter 12. The first element unit 71 includes, for example, the multiple first light emitters 11 and the multiple second light emitters 12. In the example, the second light emitters 12 are arranged with the first light emitters 11 in the X-axis direction. In other words, in the sign lamp 210, the first element unit 71 is substantially the same as that of the display device 110 of the first embodiment recited above. For example, the first element unit 71 and the second element unit 72 have line configurations extending in the Y-axis direction. The first light emitters 11 and the second light emitters 12 are formed in configurations corresponding to the pattern of the first element unit 71.

The second element unit 72 includes a fourth organic layer 24. The fourth organic layer 24 includes an organic light-emitting layer. The fourth organic layer 24 emits a fourth light L4 having a fourth light emission spectrum. A fourth color (the fourth light emission spectrum) of the fourth light L4 is different from the mixed color of the first color, the second color, and the third color of the first to third lights L1 to L3 emitted from the first element unit 71. For example, the fourth organic layer 24 is formed in a configuration corresponding to the pattern of the second element unit 72.

For example, in the case where the first color C1 is set to blue, the second color C2 is set to red, and the third color C3 is set to green, the mixed color of the first color, the second color, and the third color is substantially white. In such a case, the fourth color is a color different from white. In the example, the fourth color is, for example, green. For example, the fourth color is substantially the same as the third color. In the example, the fourth organic layer 24 is, for example, substantially the same as the third organic layer 23. The fourth organic layer 24 includes, for example, the second phosphorescent material.

The sign lamp 210 displays a pattern colored with the fourth color and the mixed color of the first to third colors by using the first element unit 71 and the second element unit 72. For example, the sign lamp 210 displays a pattern (a pictogram) for evacuation guidance that is colored with white and green.

For example, as shown in FIG. 5A, a pattern that is colored with white and red may be displayed by setting the first color C1 to blue, setting the second color C2 to green, setting the third color C3 to red, and setting the fourth color C4 to red. Thereby, for example, the sign lamp can be used favorably as a medical sign lamp, etc. For example, the fourth color of the fourth organic layer 24 may be the same as the first color or may be the same as the second color. The fourth color may be different from the first to third colors. However, as recited above, the fourth organic layer 24 is set to be substantially the same as the third organic layer 23. Thereby, for example, the third organic layer 23 and the fourth organic layer 24 can be formed simultaneously. For example, the manufacturing processes of the sign lamp 210 can be simplified.

The sign lamp 210 further includes, for example, the first to fourth electrodes 31 to 34, the substrate 40, and the insulating layer 50. In the sign lamp 210, the configuration of the first element unit 71 is substantially the same as that of the light-emitting device 110 of the first embodiment recited above; and a detailed description is therefore omitted.

In the sign lamp 210, the first electrode 31 is electrically connected also to the fourth organic layer 24. The fourth electrode 34 is electrically connected to the fourth organic layer 24. In the example, the fourth organic layer 24 is provided between the first electrode 31 and the fourth electrode 34. Thereby, light is emitted from the fourth organic layer 24 by applying a voltage between the first electrode 31 and the fourth electrode 34.

The substrate 40 is arranged with the first element unit 71 and the second element unit 72 in the Z-axis direction. The substrate 40 opposes the first electrode 31 in the Z-axis direction. In the example, the second electrode 32 is provided between the substrate 40 and the first electrode 31. The first light emitter 11 is provided between the second electrode 32 and the first electrode 31. The third electrode 33 is provided between the substrate 40 and the first electrode 31. The second light emitter 12 is provided between the third electrode 33 and the first electrode 31. The fourth electrode 34 is provided between the substrate 40 and the first electrode 31. The fourth organic layer 24 is provided between the fourth electrode 34 and the first electrode 31.

Similarly to the light-emitting device 110, the sign lamp 210 is, for example, the bottom-emission type. For example, the fourth electrode 34 is light-transmissive. For example, the fourth light L4 that is emitted from the fourth organic layer 24 passes through the fourth electrode 34 and the substrate 40 and is emitted to the outside.

For example, the insulating layer 50 is provided also between the first element unit 71 and the second element unit 72. For example, the insulating layer 50 is filled into the gap between the first element unit 71, the second element unit 72, the first electrode 31, and the substrate 40.

In the sign lamp 210, the first light emitter 11 and the second light emitter 12 are provided in the first element unit 71. Thereby, similarly to the light-emitting devices of the first embodiment recited above, high luminous efficiency and the display of various colors can be realized. For example, white having a high color temperature can be realized.

FIG. 9 is a partial cross-sectional view schematically showing a portion of another sign lamp according to the second embodiment.

In the sign lamp 211 as shown in FIG. 9, the first electrode 31 is light-transmissive; and the second electrode 32, the third electrode 33, and the fourth electrode 34 are light-reflective.

In the sign lamp 211, the light that is emitted from the first light emitter 11 passes through the first electrode 31 and is emitted to the outside. The light that is emitted from the second light emitter 12 passes through the first electrode 31 and is emitted to the outside. The light that is emitted from the fourth organic layer 24 passes through the first electrode 31 and is emitted to the outside. In other words, the sign lamp 211 is a so-called top-emission type. Thus, the sign lamp according to the embodiment may be the bottom-emission type or may be the top-emission type.

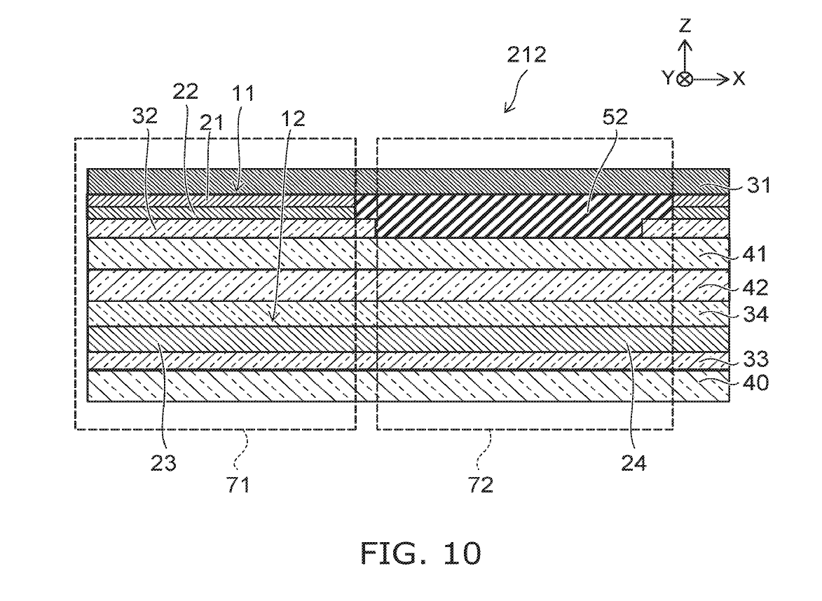

FIG. 10 is a partial cross-sectional view schematically showing a portion of another sign lamp according to the second embodiment.

In the sign lamp 212 as shown in FIG. 10, the second light emitter 12 is arranged with the first light emitter 11 in the Z-axis direction. In other words, in the sign lamp 212, the first element unit 71 is substantially the same as that of the light-emitting device 112. Accordingly, a detailed description of the first element unit 71 is omitted.

In the second element unit 72 of the sign lamp 212, an insulating layer 52 is provided between the first electrode 31 and the substrate 40. The substrate 41 is provided between the insulating layer 52 and the substrate 40. The substrate 42 is provided between the substrate 41 and the substrate 40. The fourth electrode 34 is provided between the substrate 42 and the substrate 40. The fourth organic layer 24 is provided between the fourth electrode 34 and the substrate 40. The third electrode 33 is provided between the fourth organic layer 24 and the substrate 40.

In the sign lamp 212, the fourth organic layer 24 is continuous with the third organic layer 23. In the example, the material of the fourth organic layer 24 is substantially the same as the material of the third organic layer 23. In other words, in the example, the third organic layer 23 and the fourth organic layer 24 are one continuous layer.

For example, the insulating layer 52 is filled into the gap between the first electrode 31 and the substrate 41. For example, in the second element unit 72, the insulating layer 52 is filled into the gap of the size of the first light emitter 11 of the first element unit 71. The insulating layer 52 is, for example, light-transmissive.

In the example, the first electrode 31 is, for example, light-reflective. The second to fourth electrodes 32 to 34 and the substrates 40 to 42 are light-transmissive. Thereby, the light that is emitted from the first light emitter 11, the second light emitter 12, and the fourth organic layer 24 is emitted from the substrate 40 to the outside. In other words, the device is the bottom-emission type.

For example, the third electrode 33 may be light-reflective; and the first electrode 31, the second electrode 32, the fourth electrode 34, the substrates 41 and 42, and the insulating layer 52 may be light-transmissive. In such a case, the light that is emitted from the first light emitter 11, the second light emitter 12, and the fourth organic layer 24 is emitted from the first electrode 31 to the outside. In other words, the device is the top-emission type.

According to such a light-emitting device, the first element unit can be a portion where the light emission color is changed; the second element unit can be a portion where the light emission color is not changed; and a light-emitting device in which the light emission colors are switchable can be obtained.

In the sign lamp 212 as well, similarly to the embodiments recited above, high luminous efficiency and the display of various colors can be realized. For example, white having a high color temperature can be realized.

### Third Embodiment

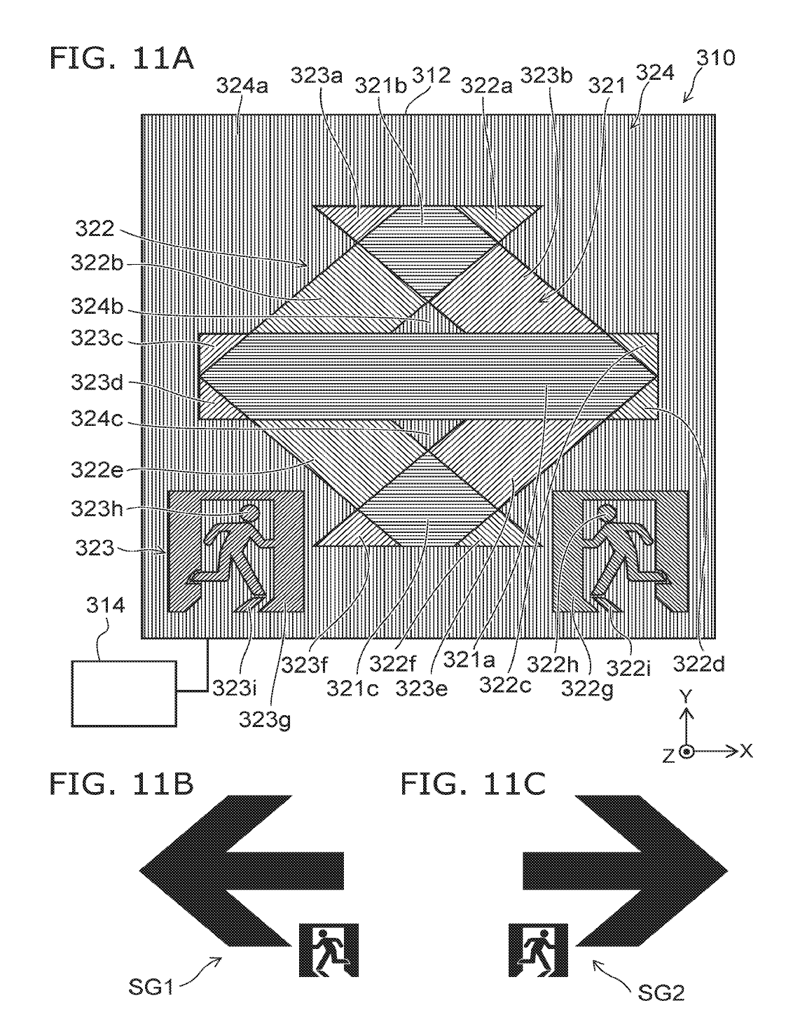

FIG. 11A to FIG. 11C are schematic views showing a sign lamp according to a third embodiment.

FIG. 11A is a plan view schematically showing the sign lamp 310. FIGS. 11B and 11C are schematic views showing examples of the patterns displayed by the sign lamp 310.

As shown in FIG. 11A, the sign lamp 310 includes a display unit 312 and a controller 314.

The display unit 312 includes multiple segments 321 to 324. The segments 321 to 324 emit light of different multiple colors. In the example, each of the segments 321 to 324 emits white light and green light. The colors emitted by the segments 321 to 324 are not limited thereto and may be any color. Two or more colors may be emitted by each of the segments 321 to 324. The display unit 312 may include, for example, a segment that emits light of only one color.

Each of the segments 321 to 324 is made of multiple region units separated in the plane; and the color of the light radiated by the region units belonging to the same segment changes synchronously. For example, the segment 321 includes region units 321a to 321c. The segment 322 includes region units 322a to 322i. The segment 323 includes region units 323a to 323i. The segment 324 includes region units 324a to 324c.

The controller 314 selects the color of the light emitted from each of the segments 321 to 324. Thereby, the controller 314 selectively displays different multiple patterns in the display unit 312. In the example, the controller 314 selectively switches between a pattern SG1 shown in FIG. 11B and a pattern SG2 shown in FIG. 11C. For example, the patterns may be switched in two or more types of switching schemes.

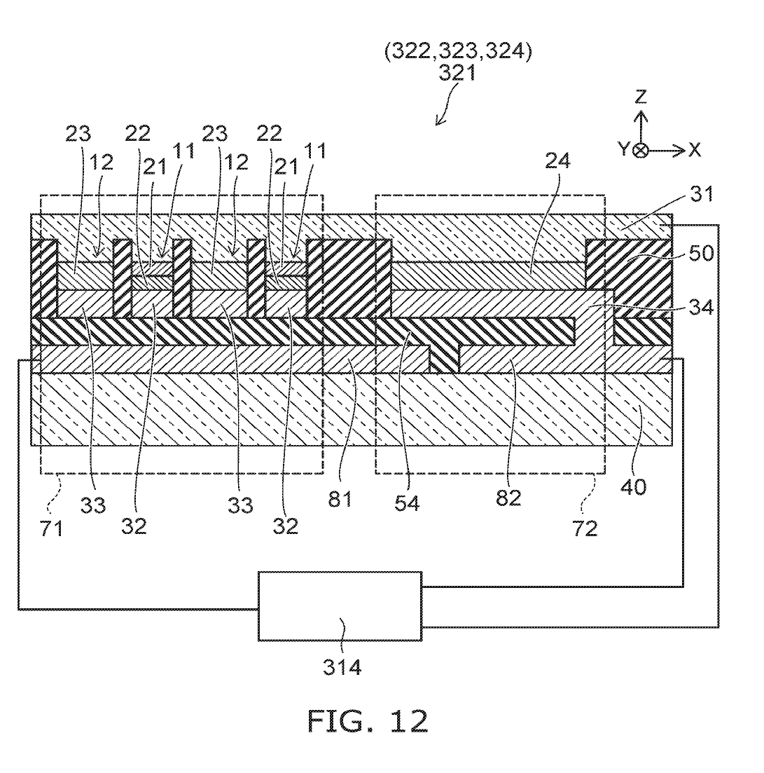

FIG. 12 is a cross-sectional view schematically showing an example of a segment.

As shown in FIG. 12, each of the segments 321 to 324 includes the first element unit 71 and the second element unit 72. For example, each of the segments 321 to 324 includes the multiple first element units 71 and the multiple second element units 72. For example, each of the first element units 71 and each of the second element units 72 has a line configuration extending in the Y-axis direction. For example, the first element units 71 and the second element units 72 are arranged alternately in the X-axis direction. Each of the first element units 71 and each of the second element units 72 is formed in a configuration corresponding respectively to the segments 321 to 324.

In the example, the first light emitter 11, the second light emitter 12, the fourth organic layer 24, etc., are substantially the same as those described in reference to the sign lamp 211; and a detailed description is therefore omitted. In each of the segments 321 to 324, the first element unit 71 and the second element unit 72 may be the bottom-emission type or may be the top-emission type.

Each of the segments 321 to 324 further includes, for example, an insulating layer 54 and interconnects 81 and 82. For example, the interconnect 81 is provided between the substrate 40 and each of the second electrodes 32 and between the substrate 40 and each of the third electrodes 33. For example, the interconnect 81 opposes each of the second electrodes 32 and each of the third electrodes 33 in the Z-axis direction.

For example, the interconnect 82 is provided between the fourth electrode 34 and the substrate 40. For example, the insulating layer 54 is provided between the interconnect 81 and each of the second electrodes 32, between the interconnect 81 and each of the third electrodes 33, and between the fourth electrode 34 and the interconnect 82.

For example, the interconnect 81 is electrically connected to each of the second electrodes 32 and each of the third electrodes 33 by vias, etc. For example, the interconnect 82 is electrically connected to the fourth electrode 34 by a via, etc. For example, the interconnect 81 and the interconnect 82 are electrically insulated from each other by the insulating layer 54, etc. For example, the interconnect 81 and the interconnect 82 are insulated from each other between the segments 321 to 324 as well. For example, the interconnect 81 of the segment 321 is electrically insulated from the interconnect 81 of the segment 322. Thereby, in the sign lamp 310, voltages can be applied individually to each of the interconnects 81 and 82.

For example, the controller 314 is electrically connected to the first electrode 31 and the interconnects 81 and 82.

For example, the controller 314 applies a voltage between the first electrode 31 and the interconnect 81. Thereby, light is emitted from each of the first light emitters 11 and each of the second light emitters 12. For example, substantially white light is emitted from each of the first light emitters 11 and each of the second light emitters 12. In other words, substantially white light is emitted from the segments 321 to 324.

For example, the controller 314 also applies a voltage between the first electrode 31 and the interconnect 82. Thereby, light is emitted from the fourth organic layer 24. For example, substantially green light is emitted from the fourth organic layer 24. In other words, substantially green light is emitted from the segments 321 to 324.

Thus, the controller 314 is electrically connected to the multiple first element units 71 and the multiple second element units 72 of each of the segments 321 to 324. Then, the lit state and the unlit state of each of the multiple first element units 71 and the multiple second element units 72 are controlled. In other words, it is controlled whether to apply the voltage between the first electrode 31 and the interconnect 81 or apply the voltage between the first electrode 31 and the interconnect 82.

Thereby, the color of the light emitted from each of the segments 321 to 324 can be selectively switched. In other words, the controller 314 selectively displays different multiple patterns. For example, the sign lamp 310 can selectively switch between the display of the pattern SG1 and the display of the pattern SG2. For example, the controller 314 switches the color of the light emitted from each of the segments 321 to 324 according to a control signal, the setting of a selection switch, or the like that is input from the outside.

In the sign lamp 310 as well, the first light emitter 11 and the second light emitter 12 are provided in the first element unit 71. Thereby, similarly to the light-emitting devices of the first embodiment recited above, high luminous efficiency and the display of various colors can be realized. For example, white having a high color temperature can be realized.

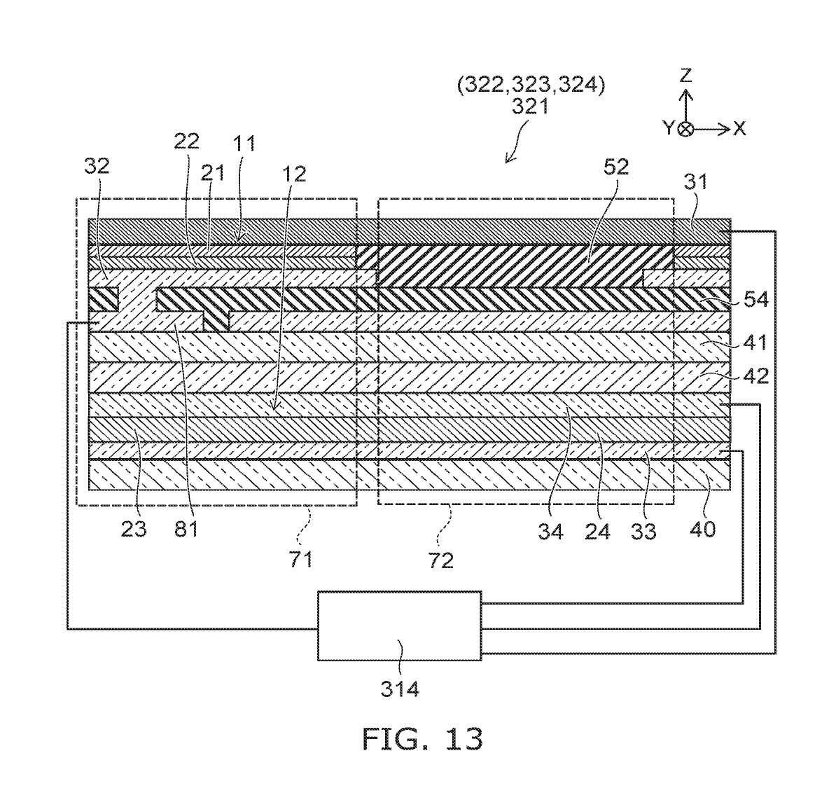

FIG. 13 is a cross-sectional view schematically showing another example of a segment.

In the example as shown in FIG. 13, the first light emitter 11, the second light emitter 12, the fourth organic layer 24, etc., are substantially the same as those described in reference to the sign lamp 212; and a detailed description is therefore omitted. In each of the segments 321 to 324 of the example, the first element unit 71 and the second element unit may be the bottom-emission type or may be the top-emission type.

Each of the segments 321 to 324 further includes, for example, the insulating layer 54 and the interconnects 81 and 82. In the example, the interconnect 81 is provided between the second electrode 32 and the substrate 41. The insulating layer 54 is provided between the second electrode 32 and the interconnect 81.

For example, the interconnect 81 is electrically connected to the second electrode 32 by a via, etc. The interconnects 81 of the segments 321 to 324 are electrically insulated from each other. Thereby, the voltages can be applied individually to the interconnects 81 of the segments 321 to 324.

In the example, for example, the controller 314 is electrically connected to the first electrode 31, the third electrode 33, the fourth electrode 34, and the interconnect 81.

For example, the controller 314 applies a voltage between the first electrode 31 and the interconnect 81 and applies a voltage between the third electrode 33 and the fourth electrode 34. Thereby, substantially white light is emitted from the segments 321 to 324.

For example, the controller 314 also applies the voltage between the third electrode 33 and the fourth electrode 34. Thereby, substantially green light is emitted from the segments 321 to 324.

In the example as well, the first light emitter 11 and the second light emitter 12 are provided in the first element unit 71. Thereby, similarly to the embodiments recited above, high luminous efficiency and the display of various colors can be realized. For example, white having a high color temperature can be realized.

### Fourth Embodiment

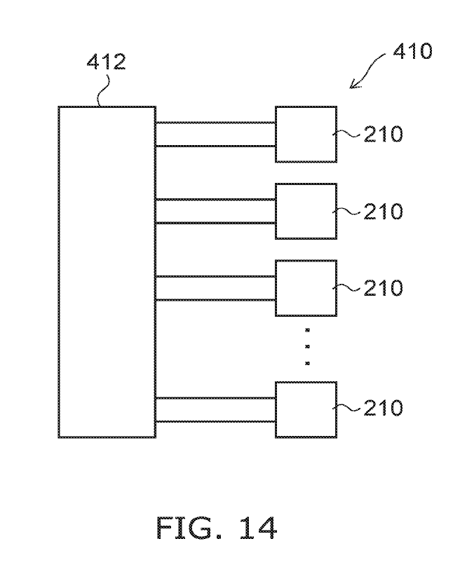

FIG. 14 is a block diagram schematically showing a display system according to a fourth embodiment.

As shown in FIG. 14, the display system 410 includes the multiple sign lamps 210 and a controller 412. The controller 412 is electrically connected to each of the multiple sign lamps 210. For example, the controller 412 is electrically connected to the first to fourth electrodes 31 to 34 of each of the multiple sign lamps 210. Thereby, the controller 412 controls the lit state and the unlit state of each of the multiple sign lamps 210.

For example, the sign lamps 210 are escape route lighting for evacuation guidance. In such a case, in the display system 410, the evacuees can be guided more appropriately to exits, etc., by controlling the lit state and the unlit state of each of the sign lamps 210 according to the state of the disaster. For example, when the disaster occurs, the evacuees can be guided to exits distal to the origin of the fire.

In the display system 410, for example, high luminous efficiency and the display of various colors can be realized for each of the sign lamps 210. For example, white having a high color temperature can be realized.

In the example, the sign lamps 210 are used in the display system 410. The sign lamps that are used in the display system 410 are not limited to the sign lamps 210. For example, the sign lamps 211 and the sign lamps 212 may be used in the display system 410.

Also, the sign lamps 310 may be used in the display system 410. For example, the patterns of the sign lamps 310 are switched according to the control signal from the controller 412. In such a case, for example, the controller 412 is electrically connected to the controllers 314 of the sign lamps 310. For example, the controller 412 is used as a main controller; the controllers 314 are used as sub controllers; and the operations of the controller 314 of each of the multiple sign lamps 310 are controlled by the controller 412. Thereby, for example, in the case where the sign lamps 310 are escape route lighting, the guiding can be performed more appropriately.

The electrical connection between the controller 412 and each of the sign lamps may be wired or may be wireless. For example, the electrical connection between the controller 412 and the controller 314 may be wired or may be wireless. Thus, a wireless control signal may be transmitted to each of the sign lamps via radio waves, etc., from the controller 412; and the lit state and the unlit state of each of the sign lamps may be switched according to the control signal.

In this specification, being “electrically connected” includes not only the case of being connected in direct contact but also the case of being connected via another conductive member, etc.

According to the embodiments, a light-emitting device, a sign lamp, and a display system that have high luminous efficiency and can display various colors can be provided, for example.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel. In the specification of the application, a state of “provided on” includes a state to be provided having another element being inserted therebetween in addition to a state to be provided directly contacting. A state of “stacking” includes a state to be stacked having another element inserted therebetween in addition to a state to be provided directly contacting each other. A state of “electrically connected” includes a state to be connected through another electrical member in addition to a state to be connected directly contacting.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in light-emitting devices, sign lamps, and display systems such as first light emitter, first light emitter, first organic layer, second organic layer, third organic layer, first element unit, second element unit, and controller, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all light-emitting devices, sign lamps, and display systems practicable by an appropriate design modification by one skilled in the art based on the light-emitting device, sign lamp, and display system described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light-emitting device, comprising:
a first light emitter including
a first organic layer including a fluorescent material to emit a first light having a first light emission spectrum, and
a second organic layer stacked with the first organic layer in a first direction, the second organic layer including a first phosphorescent material to emit a second light having a second light emission spectrum different from the first light emission spectrum; and
a second light emitter including a third organic layer to emit a third light having a third light emission spectrum different from the first light emission spectrum and the second light emission spectrum,
a triplet energy of the fluorescent material being higher than a triplet energy of the first phosphorescent material.

2. The device according to claim 1, wherein a white light is obtained by adding the first light emission spectrum, the second light emission spectrum, and the third light emission spectrum.

3. The device according to claim 1, wherein
in (x, y) chromaticity coordinates of CIE 1931, a first region surrounded with a first color of the first light emission spectrum, a second color of the second light emission spectrum, and a third color of the third light emission spectrum includes a second region surrounded with a first point, a second point, a third point, and a fourth point,
the (x, y) chromaticity coordinates of the first point are (0.350, 0.360),
the (x, y) chromaticity coordinates of the second point are (0.305, 0.315),
the (x, y) chromaticity coordinates of the third point are (0.295, 0.325), and
the (x, y) chromaticity coordinates of the fourth point are (0.340, 0.370).

4. The device according to claim 3, wherein
the first region further includes a third region surrounded with a fifth point, a sixth point, a seventh point, and an eighth point,
the (x, y) chromaticity coordinates of the fifth point are (0.500, 0.405),
the (x, y) chromaticity coordinates of the sixth point are (0.300, 0.300),
the (x, y) chromaticity coordinates of the seventh point are (0.300, 0.340), and
the (x, y) chromaticity coordinates of the eighth point are (0.500, 0.445).

5. The device according to claim 3, wherein
the (x, y) chromaticity coordinates of the first color are included in a region surrounded with (0.05, 0.3), (0.187, 0.35), (0.26, 0.154), and (0.174, 0.005),
the (x, y) chromaticity coordinates of the second color are included in a region surrounded with (0.65, 0.22), (0.6, 0.3), (0.6, 0.4), and (0.74, 0.26), and
the (x, y) chromaticity coordinates of the third color are included in a region surrounded with (0.38, 0.62), (0.3, 0.45), and (0, 0.65).

6. The device according to claim 3, wherein
the (x, y) chromaticity coordinates of the first color are included in a region surrounded with (0.05, 0.3), (0.187, 0.35), (0.26, 0.154), and (0.174, 0.005),
the (x, y) chromaticity coordinates of the second color are included in a region surrounded with (0.38, 0.62), (0.3, 0.45), and (0, 0.65), and
the (x, y) chromaticity coordinates of the third color are included in a region surrounded with (0.65, 0.22), (0.6, 0.3), (0.6, 0.4), and (0.74, 0.26).

7. The device according to claim 1, wherein the second light emitter is arranged with the first light emitter in a second direction perpendicular to the first direction.

8. The device according to claim 7, further comprising a first electrode, a second electrode, and a third electrode,
the first light emitter being provided between the first electrode and the second electrode,
the second light emitter being provided between the first electrode and the third electrode.

9. The device according to claim 1, wherein the second light emitter is arranged with the first light emitter in the first direction.

10. The device according to claim 9, further comprising a first electrode, a second electrode, and a third electrode,
the first light emitter being provided between the first electrode and the second electrode,
the second light emitter being provided between the first electrode and the third electrode.

11. The device according to claim 1, further comprising a first light-emitting region and a second light-emitting region, the first light-emitting region including the first light emitter and the second light emitter, the second light-emitting region being arranged with the first light-emitting region in a first surface intersecting the first direction,
the second light-emitting region including a fourth organic layer emitting the fourth light having the fourth light emission spectrum.

12. The device according to claim 11, wherein the third organic layer and the fourth organic layer include a second phosphorescent material different from the first phosphorescent material.

13. A sign lamp, comprising:
a first element unit including
a first light emitter including
a first organic layer including a fluorescent material to emit a first light having a first light emission spectrum, and
a second organic layer stacked with the first organic layer in a first direction, the second organic layer including a first phosphorescent material to emit a second light having a second light emission spectrum different from the first light emission spectrum, and
a second light emitter including a third organic layer to emit a third light having a third light emission spectrum different from the first light emission spectrum and the second light emission spectrum,
a triplet energy of the fluorescent material being higher than a triplet energy of the first phosphorescent material; and
a second element unit arranged with the first element unit in a second direction perpendicular to the first direction, the second element unit being configured to emit a fourth light of a fourth color, the fourth color being different from a mixed color of a first color of the first light emission spectrum, a second color of the second light emission spectrum, and a third color of the third light emission spectrum,
the sign lamp being configured to display a pattern colored with the mixed color and the fourth color by using the first element unit and the second element unit.

14. The sign lamp according to claim 13, further comprising a controller electrically connected to each of the first element unit and the second element unit, the controller controlling a lit state and an unlit state of each of the first element unit and the second element unit,
each of the first element unit and the second element unit being multiply provided,
the controller being electrically connected to each of the plurality of first element units and the plurality of second element units, the controller selectively displaying a mutually-different plurality of the patterns by controlling a lit state and an unlit state of each of the plurality of first element units and the plurality of second element units.

15. A display system, comprising:
a plurality of sign lamps; and
a controller,
each of the plurality of sign lamps including
a first element unit including
a first light emitter including
a first organic layer including a fluorescent material to emit a first light having a first light emission spectrum, and
a second organic layer stacked with the first organic layer in a first direction, the second organic layer including a first phosphorescent material to emit a second light having a second light emission spectrum different from the first light emission spectrum, and
a second light emitter including a third organic layer to emit a third light having a third light emission spectrum different from the first light emission spectrum and the second light emission spectrum,
a triplet energy of the fluorescent material being higher than a triplet energy of the first phosphorescent material, and
a second element unit arranged with the first element unit in a second direction perpendicular to the first direction, the second element unit emitting a fourth light of a fourth color, the fourth color being different from a mixed color of a first color of the first light emission spectrum, a second color of the second light emission spectrum, and a third color of the third light emission spectrum,
each of the plurality of sign lamps being configured to display a pattern colored with the mixed color and the fourth color by using the first element unit and the second element unit,
the controller being electrically connected to each of the plurality of sign lamps, the controller being configured to control a lit state and an unlit state of each of the plurality of sign lamps.
